(19) United States
(12) Patent Application Publication
(10) Pub. No.: US 2022/0134475 A1
(43) Pub. Date: May 5, 2022

(54) SYSTEMS AND METHODS FOR FORMING PARTIAL NANO-PERFORATIONS WITH VARIABLE BESSEL BEAM

(71) Applicant: CORNING INCORPORATED, CORNING, NY (US)

(72) Inventors: Andreas Simon Gaab, Grobenzell (DE); Anping Liu, Horseheads, NY (US); Jian-Zhi Jay Zhang, Ithaca, NY (US)

(21) Appl. No.: 17/510,615

(22) Filed: Oct. 26, 2021

Related U.S. Application Data
(60) Provisional application No. 63/107,824, filed on Oct. 30, 2020.

(51) Int. Cl. B23K 26/06

(52) U.S. Cl. CPC B23K 26/0648; H01L 21/4803; B23K 26/0665

(57) ABSTRACT

Embodiments of the present disclosure include a optical assembly comprising: an axicon lens with spherical aberration configured to generate the laser beam focal line, an optical element set spaced part from the optical lens, and a focusing optical element spaced apart from the optical element set, wherein the axicon lens and the optical element set are translatable relative to each other along the laser beam propagation direction and wherein the focusing optical element is in a fixed position along the laser beam propagation direction.

### CROSS-REFERENCE TO RELATED APPLICATIONS

This application claims the benefit of priority under 35 U.S.C. § 119 of U.S. Provisional Application Ser. No. 63/107,824 filed on Oct. 30, 2020, the content of which is relied upon and incorporated herein by reference in its entirety.

### FIELD

The present disclosure relates to systems and methods of forming partial nano-perforations, and in particular systems and methods of forming partial nano-perforations with variable Bessel beams in glass wafers for semiconductor substrates.

### BACKGROUND

As the semiconductor industry continues to advance, functionality and value per unit wafer area continue to increase. Minimizing wafer dicing loss becomes more and more important. This is especially true when the die size is small, as is the case with RF chips used in mobile devices, for example. Another extreme example may be RFID chips, which can be a fraction of 1 mm in each dimension.

While Si is the dominant semiconductor material, its semiconducting nature also leads to detrimental effects in certain applications. One example is RF, where the EM field can interact with the charges in the Si substrate to cause signal loss, signal cross-talk, and nonlinearity. Glass and ceramic materials can deliver superior performance in such cases due to the “passive” nature of such materials. There are many technologies that enable active semiconductor devices to be built on, or transferred to, a glass or ceramic substrate. Well known examples are SOS (silicon-on-sapphire) and SoG (silicon-on-glass).

Once the device layers are made or transferred onto a glass, Si is completely removed through grinding and chemical etching. The glass substrate serves as a mechanical support throughout this process. The glass is then mechanically thinned to 100 μm to 150 μm through grinding, before individual die are singulated and packaged.

If each die is 0.5 mm×0.5 mm in size, typical diamond blade dicing results in 80 μm to 100 μm kerf loss, representing up to 30% areal loss. If an alternative near-zero kerf loss method can be had, this valuable real estate would be saved, delivering significant value to the wafer customer.

Accordingly, the inventors have developed improved systems and methods of forming partial nano-perforations with variable Bessel beams in glass wafers for semiconductor substrates.

### SUMMARY

Additional features and advantages are set forth in the Detailed Description that follows, and in part will be readily apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

A first embodiment of the present disclosure includes a method, comprising focusing a pulsed laser beam into a laser beam focal line oriented along the laser beam propagation direction via an optical assembly positioned in the beam path of the laser on the beam emergence side of the optical assembly, the optical assembly including: an axicon lens with spherical aberration configured to generate the laser beam focal line, an optical element set spaced part from the optical lens, and a focusing optical element spaced apart from the optical element set, wherein the axicon lens and the optical element set are translatable relative to each other along the laser beam propagation direction and wherein the focusing optical element is in a fixed position along the laser beam propagation direction; directing the laser beam focal line into a glass material having a thickness of less than 5 mm, the laser beam focal line generating an induced absorption within the glass material, the induced absorption producing a perforation along the laser beam focal line within the material; adjusting the distance between the axicon lens and the optical element to adjust the depth of the laser beam focal line within the material translating the glass material and the laser beam relative to each other, thereby laser drilling a plurality of perforations along a first plane within the material, wherein the depth of the perforation is less than half of the thickness of the material.

A second embodiment of the present disclosure may include the first embodiment, further comprising thinning the glass material to expose a first end of the plurality of perforations to at least one surface; and expand the plurality of perforations through the thickness.

A third embodiment of the present disclosure may include the first embodiment, wherein a distance between the axicon lens and the optical element set is about 85 to about 110 mm.

A fourth embodiment of the present disclosure may include the first embodiment, wherein a distance between the optical element set and the focusing optical element is about 30 to about 90 mm.

A fifth embodiment of the present disclosure may include the first to fourth embodiment, wherein a depth of the laser beam focal line within the glass material is about 0.32 to about 0.98 mm.

A sixth embodiment of the present disclosure may include the first to fifth embodiment, wherein the optical element set comprises two lens spaced a second distance apart.

A seventh embodiment of the present disclosure may include the sixth embodiment, wherein the second distance is about 1 mm to about 50 mm.

A eighth embodiment of the present disclosure may include the first embodiment, wherein further comprising forming an semiconductor device on the surface of the glass material after drilling a plurality of perforations along a first plane within the material.

A ninth embodiment of the present disclosure may include the eighth embodiment, wherein further comprising thinning the glass material after forming the semiconductor device on the surface of the glass material to expose an opening of the perforations.

A tenth embodiment of the present disclosure includes a method, comprising focusing a pulsed laser beam into a laser beam focal line oriented along the laser beam propagation direction via an optical assembly positioned in the beam path of the laser on the beam emergence side of the optical assembly, the optical assembly including: a first optical element set comprising an axicon lens, a collimation lens, and a focusing lens, wherein the axicon lens, the collimation lens, and the focusing lens are in a fixed position, a second optical element set comprising three aspherical lens, wherein the first aspherical lens and the second aspherical lens are translatable relative to each other along the laser beam propagation direction and wherein the third aspherical lens is in a fixed position along the laser beam propagation direction; directing the laser beam focal line into a glass material having a thickness of less than 5 mm, the laser beam focal line generating an induced absorption within the glass material, the induced absorption producing a perforation along the laser beam focal line within the material; adjusting the distance between the first aspherical lens and the second aspherical lens to adjust the depth of the laser beam focal line within the material; translating the glass material and the laser beam relative to each other, thereby laser drilling a plurality of perforations along a first plane within the material, wherein the depth of the perforation is less than half of the thickness of the material.

A eleventh embodiment of the present disclosure may include the tenth embodiment, further comprising thinning the glass material to expose a first end of the plurality of perforations to at least one surface; and expand the plurality of perforations through the thickness.

A twelfth embodiment of the present disclosure may include the tenth embodiment, wherein a distance between the first aspherical lens and the second aspherical lens is about 50 to about 71 mm.

A thirteenth embodiment of the present disclosure may include the tenth embodiment, wherein between the second aspherical lens and the third aspherical lens is about 31 to about 48 mm.

A fourteenth embodiment of the present disclosure may include the tenth embodiment, wherein a depth of the laser beam focal line within the material is about 0.43 to about 0.66 mm.

A fifteenth embodiment of the present disclosure may include the tenth embodiment, wherein further comprising forming an semiconductor device on the surface of the glass material after drilling a plurality of perforations along a first plane within the material.

A sixteenth embodiment of the present disclosure may include the tenth embodiment, wherein further comprising thinning the glass material forming the semiconductor device on the surface of the glass material to expose an opening of the perforations.

A seventeenth embodiment of the present disclosure includes an optical assembly, comprising an axicon lens with spherical aberration configured to generate the laser beam focal line, an optical element set spaced part from the optical lens, and a focusing optical element spaced apart from the optical element set, wherein the axicon lens and the optical element set are translatable relative to each other along the laser beam propagation direction and wherein the focusing optical element is in a fixed position along the laser beam propagation direction.

A eighteenth embodiment of the present disclosure may include the seventeenth embodiment, wherein a distance between the axicon lens and the optical element set is about 85 to about 110 mm.

A nineteenth embodiment of the present disclosure may include the seventeenth embodiment, wherein a distance between the optical element set and the focusing optical element is about 30 to about 90 mm.

A twentieth embodiment of the present disclosure may include the seventeenth embodiment, wherein the optical element set comprises two lenses spaced a second distance apart.

A twenty-first embodiment of the present disclosure may include the seventeenth embodiment, wherein the second distance is about 1 mm to about 50 mm.

A twenty-second embodiment of the present disclosure includes an optical assembly comprising a first optical element set comprising an axicon lens, a collimation lens, and a focusing lens, wherein the axicon lens, the collimation lens, and the focusing lens are in a fixed position, a second optical element set comprising three aspherical lens, wherein the first aspherical lens and the second aspherical lens are translatable relative to each other along the laser beam propagation direction and wherein the third aspherical lens is in a fixed position along the laser beam propagation direction.

A twenty-third embodiment of the present disclosure may include the twenty-second embodiment, wherein a distance between the first aspherical lens and the second aspherical lens is about 50 to about 71 mm.

A twenty-fourth embodiment of the present disclosure may include the twenty-second embodiment, wherein a distance between the second aspherical lens and the third aspherical lens is about 31 to about 48 mm.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description serve to explain principles and operation of the various embodiments. As such, the disclosure will become more fully understood from the following Detailed Description, taken in conjunction with the accompanying Figures, in which:

FIG. 1 is a flowchart of an exemplary method of forming nano-perforations in a glass material, in accordance with some embodiments of the present disclosure;

FIGS. 2A and 2B are schematic illustrations of positioning of the laser beam focal line, i.e., laser processing of a material transparent to the laser wavelength due to the induced absorption along the focal line in accordance with some embodiments of the present disclosure;

FIGS. 3A-1, 3A-2, 3A-3, and 3A-4 illustrate various possibilities for processing the substrate by forming the laser beam focal line at different positions within the transparent material relative to the substrate in accordance with some embodiments of the present disclosure;

FIG. 4 is a schematic illustration of an optical assembly for laser processing in accordance with some embodiments of the present disclosure;

FIG. 5 is a schematic illustration of an optical assembly for laser processing in accordance with some embodiments of the present disclosure;

FIG. 6 depicts an exemplary glass blank in accordance with some embodiments of the present disclosure;

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

In this document, relational terms, such as first and second, top and bottom, and the like, are used solely to distinguish one entity or action from another entity or action, without necessarily requiring or implying any actual such relationship or order between such entities or actions.

It will be understood by one having ordinary skill in the art that construction of the described disclosure, and other components, is not limited to any specific material. Other exemplary embodiments of the disclosure disclosed herein may be formed from a wide variety of materials, unless described otherwise herein.

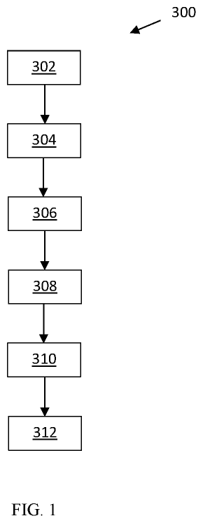

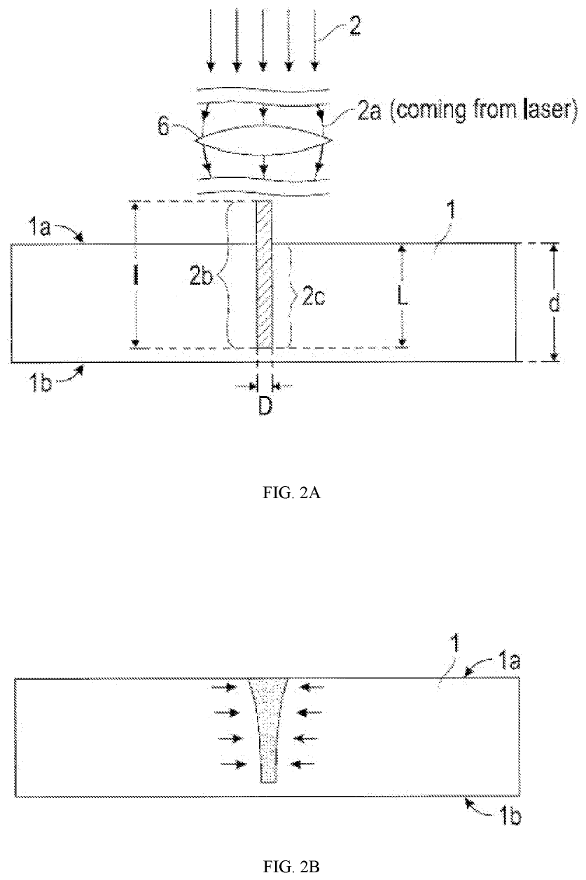

FIG. 1 depicts a flowchart of a method 300. The method 300 comprises the steps 302-312. At step 302, a pulsed laser beam 2, as shown in FIGS. 2A and 2B, is focused into a laser beam focal line 2b oriented along the laser beam propagation direction via an optical assembly positioned in the beam path of the laser on the beam emergence side of the optical assembly. Laser beam focal line 2b is a region of high energy density.

As shown in FIG. 2A, laser 3 (not shown) emits laser beam 2, which has a portion 2a incident to optical assembly 6. The optical assembly 6 turns the incident laser beam into an extensive laser beam focal line 2b on the output side over a defined expansion range along the beam direction (length 1 of the focal line).

Embodiments of the present disclosure utilize non-diffracting beams (“NDB”) to form the laser beam focal line 2b. Typically laser processing has used Gaussian laser beams. The tight focus of a laser beam with a Gaussian intensity profile has a Rayleigh range Z_{R} given by:

$${Z}_{R} = \frac{π {n}_{o} {w}_{o}^{2}}{{λ}_{o}} . \qquad Eq . ( 1 )$$

The Rayleigh range represents the distance over which the spot size wo of the beam will increase by \sqrt{2} in a material of refractive index no at wavelength no. This limitation is imposed by diffraction. Note in Eq. (1) that the Rayleigh range is related directly to the spot size, thereby leading to the conclusion that a beam with a tight focus (i.e. small spot size) cannot have a long Rayleigh range. Such a beam will maintain this small spot size only for a very short distance. This also means that if such a beam is used to drill through a material by changing the depth of the focal region, the rapid expansion of the spot on either side of the focus will require a large region free of optical distortion that might limit the focus properties of the beam. Such a short Rayleigh range also requires multiple pulses to cut through a thick sample.

However, embodiments of the present disclosure utilize NDBs instead of the optical Gaussian beams discussed above. Non-diffracting beams may propagate for a considerable distance before diffraction effects inevitably limit the beam focus. Although an infinite NDB does not suffer from diffractive effects, a physically realizable NDB will have a limited physical extent. The central lobe of the beam can be quite small in radius and thus produce a high intensity beam. There are several types of NDBs including, but not limited to, Bessel beams, Airy beams, Weber beams and Mathieu beams whose field profiles are typically given by special functions which decay more slowly in the transverse direction than a Gaussian function.

It should be understood that, although NDBs described herein are in the context of Bessel beams, embodiments are not limited thereto. The central spot size of a Bessel beam is given by:

$$d = 2 \frac{2.405 {λ}_{o}}{NA 2 π {n}_{o}} , \qquad Eq . ( 2 )$$

where NA is the numerical aperture given by the cone of plane waves making an angle of β with the optical axis. A key difference between Bessel beams and Gaussian beams is that Rayleigh range is given by:

$${Z}_{max} = \frac{π Dd}{4 λ} , \qquad Eq . ( 3 )$$

where D is the finite extent of the beam imposed by some aperture or optical element. It is therefore shown that the aperture size D may be used to increase the Rayleigh range beyond the limit imposed by the size of the central spot. A practical method for generating Bessel beams is to pass a Gaussian beam through an axicon or an optical element with a radially linear phase element.

In general, the optical method of forming the line focus (i.e., the laser beam focal line) can take multiple forms, such as, without limitation, using donut shaped laser beams and spherical lenses, axicon lenses, diffractive elements, or other methods to form the linear region of high intensity. The type of laser (picosecond, femtosecond, and the like) and wavelength (IR, visible, UV, and the like) may also be varied, as long as sufficient optical intensities are reached to create breakdown of the substrate material.

At step 304, and referring once again to FIGS. 2A and 2B, the laser beam focal line is directed into layer 1, which is the layer of a glass substrate in which internal modifications by laser processing and two-photon absorption is to occur. Layer 1 is a component of a larger workpiece, which typically includes a substrate or carrier upon which a multilayer stack is formed. Layer 1 is the layer within the multilayer stack in which holes, cuts, or other features are to be formed through two-photon absorption assisted ablation or modification as described herein. The layer 1 is positioned in the beam path to at least partially overlap the laser beam focal line 2b of laser beam 2. Reference 1a designates the surface of the layer 1 facing (closest or proximate to) the optical assembly 6 or the laser, respectively, reference 1b designates the reverse surface of layer 1 (the surface remote, or further away from, optical assembly 6 or the laser). The thickness of the layer 1 (measured perpendicularly to the planes 1a and 1b, i.e., to the substrate plane) is labeled with d. In some embodiments the thickness of the layer is less than 5 mm.

As FIG. 2A depicts, layer 1 is aligned perpendicular to the longitudinal beam axis and thus behind the same focal line 2b produced by the optical assembly 6 (the substrate is perpendicular to the plane of the drawing). Viewed along the beam direction, the layer 1 is positioned relative to the focal line 2b in such a way that the focal line 2b (viewed in the direction of the beam) starts before the surface 1a of the layer 1 and stops before the surface 1b of the layer 1, i.e. focal line 2b terminates within the layer 1 and does not extend beyond surface 1b. In the overlapping area of the laser beam focal line 2b with layer 1, i.e. in the portion of layer 1 overlapped by focal line 2b, the extensive laser beam focal line 2b generates nonlinear absorption in layer 1. (Assuming suitable laser intensity along the laser beam focal line 2b, which intensity is ensured by adequate focusing of laser beam 2 on a section of length 1 (i.e. a line focus of length 1), which defines an extensive section 2c (aligned along the longitudinal beam direction) along which an induced nonlinear absorption is generated in the layer 1.) The induced nonlinear absorption results in formation of a defect line or crack in layer 1 along section 2c. The defect or crack formation is not only local, but rather may extend over the entire length of the extensive section 2c of the induced absorption. The length of section 2c (which corresponds to the length of the overlapping of laser beam focal line 2b with layer 1) is labeled with reference L. The average diameter or extent of the section of the induced absorption 2c (or the sections in the material of layer 1 undergoing the defect line or crack formation) is labeled with reference D. This average extent D may correspond to the average diameter 6 of the laser beam focal line 2b, that is, an average spot diameter in a range of between about 0.1 μm and about 5 μm.

As FIG. 2A shows, the layer 1 (which is transparent to the wavelength λ of laser beam 2) is locally heated due to the induced absorption along the focal line 2b. The induced absorption arises from the nonlinear effects associated with the high intensity (energy density) of the laser beam within focal line 2b. FIG. 2B illustrates that the heated layer 1 will eventually expand so that a corresponding induced tension leads to micro-crack formation, with the tension being the highest at surface 1a.

Representative optical assemblies 6, which can be applied to generate the focal line 2b, as well as a representative optical setup, in which these optical assemblies can be applied, are described below. All assemblies or setups are based on the description above so that identical references are used for identical components or features or those which are equal in their function. Therefore only the differences are described below.

To insure high quality (regarding breaking strength, geometric precision, roughness and avoidance of re-machining requirements) of the surface of separation after cracking along the contour defined by the series of perforations, the individual focal lines used to form the perforations that define the contour of cracking should be generated using the optical assembly described below (hereinafter, the optical assembly is alternatively also referred to as laser optics). The roughness of the separated surface is determined primarily by the spot size or the spot diameter of the focal line. A roughness of a surface can be characterized, for example, by an Ra surface roughness statistic (roughness arithmetic average of absolute values of the heights of the sampled surface). In order to achieve a small spot size of, for example, 0.5 μm to 2 μm in case of a given wavelength λ of laser 3 (interaction with the material of layer 1), certain requirements must usually be imposed on the numerical aperture of laser assembly 6.

In order to achieve the required numerical aperture, the optics must, on the one hand, dispose of the required opening for a given focal length, according to the known Abbe formulae (N.A.=n sin (theta), n: refractive index of the material to be processed, theta: half the aperture angle; and theta=arctan (D/2f); D: aperture, f: focal length). On the other hand, the laser beam must illuminate the optics up to the required aperture, which is typically achieved by means of beam widening using widening telescopes between the laser and focusing optics.

The spot size should not vary too strongly for the purpose of a uniform interaction along the focal line. This can, for example, be ensured (see the embodiment below) by illuminating the focusing optics only in a small, circular area so that the beam opening and thus the percentage of the numerical aperture only varies slightly.

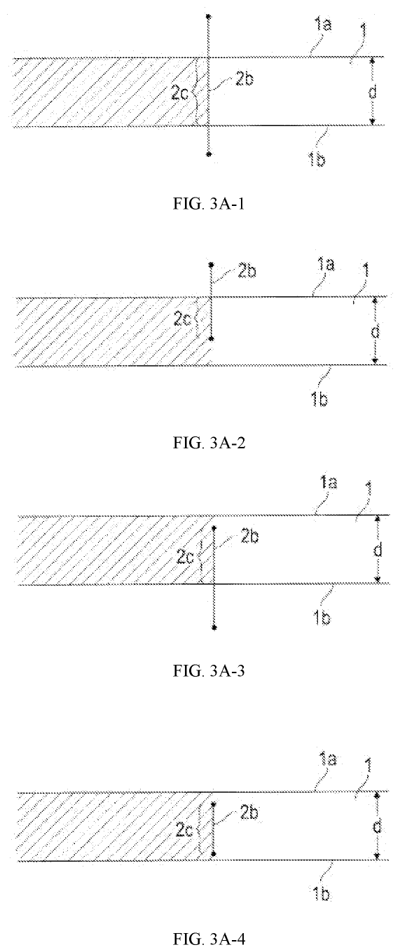

FIG. 3A-1-4 show that the position of laser beam focal line 2b can be controlled by suitably positioning and/or aligning the optical assembly 6 relative to layer 1 as well as by suitably selecting the parameters of the optical assembly 6. For example, as FIG. 3A-1 illustrates, the length 1 of the focal line 2b can be adjusted in such a way that it exceeds the layer thickness d (here by factor 2). If layer 1 is placed (viewed in longitudinal beam direction) centrally to focal line 2b, an extensive section of induced absorption 2c is generated over the entire substrate thickness.

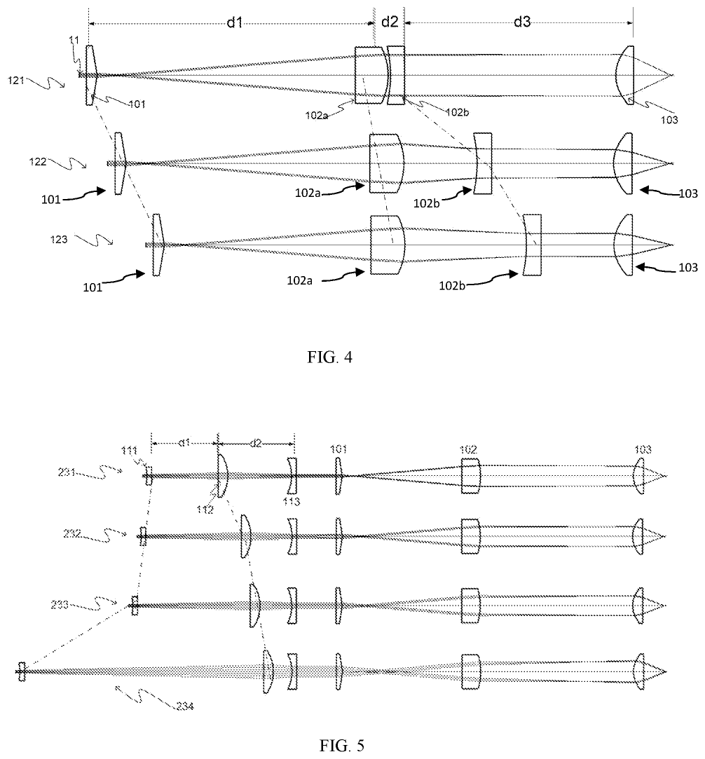

In the case shown in FIG. 3A-2, a focal line 2b of length 1 is generated which corresponds more or less to the layer thickness d. Since layer 1 is positioned relative to line 2b in such a way that line 2b starts at a point outside the material to be processed, the length L of the section of extensive induced absorption 2c (which extends here from the substrate surface to a defined substrate depth, but not to the reverse surface 1b) is smaller than the length 1 of focal line 2b. FIG. 3A-3 shows the case in which the layer 1 (viewed along the beam direction) is positioned above the starting point of focal line 2b so that, as in FIG. 3A-2, the length 1 of line 2b is greater than the length L of the section of induced absorption 2c in layer 1. The focal line thus starts within the layer 1 and extends beyond the reverse surface 1b. FIG. 3A-4 shows the case in which the focal line length 1 is smaller than the layer thickness d so that, in the case of a central positioning of the substrate relative to the focal line viewed in the direction of incidence, the focal line starts near the surface 1a within the layer 1 and ends near the surface 1b within the layer 1 (e.g. 1=0.75·d). The laser beam focal line 2b can have a length 1 in a range of between about 0.1 mm and about 100 mm or in a range of between about 0.1 mm and about 10 mm, for example. Various embodiments can be configured to have length 1 of about 0.1 mm, 0.2 mm, 0.3 mm, 0.4 mm, 0.5 mm, 0.7 mm, 1 mm, 2 mm, 3 mm or 5 mm, for example.

In some embodiments, it is particularly advantageous to position the focal line 2b in such a way that at least one of surfaces 1a, 1b is covered by the focal line, so that the section of induced nonlinear absorption 2c starts at least on one surface of the layer or material to be processed. In this way it is possible to achieve virtually ideal cuts while avoiding ablation, feathering and particulate generation at the surface.

FIG. 4 depicts an optical assembly 6 having a first configuration 121, a second configuration 122, or a third configuration 123. The optical assembly comprises a first optical element 101 (viewed along the beam direction) with a non-spherical free surface, designed to form an extensive laser beam focal line 2b, positioned in the beam path of laser 11. In some embodiments, the first optical element 101 is an axicon with a cone angle of 5°, which is positioned perpendicularly to the beam direction and centered on laser beam 11. The apex of the axicon is oriented towards the beam direction. An optical element set comprising a convex lens 102a and a concave lens 102b is spaced apart from the axicon lens 101. The convex lens 102a is positioned a distance d2 from the concave lens 102b. The optical element set 102a, 102b is positioned at a distance d1 from the axicon lens 101. A focusing lens 103 is spaced part from the optical element set 102a, 102b at a distance d3.

At step 306, and as show in FIG. 4, the axicon lens 101 and the optical element set 102a, 102b are translatable relative to each other along the laser beam propagation direction to adjust the depth of the laser beam focal line within the glass material (e.g. layer 1). For example the distance between convex lens and the concave lens 102b is increased from the first configuration 121 to the second configuration 122 and increased again from the second configuration 122 to the third configuration. The focusing lens 103 is in a fixed position along the laser beam propagation direction. Each lens is mounted on a translation stage with independent motion along the optical axis. The translation stage can be controlled by a PC with a motor or manually with conventional mechanical stages or moving barrel in a cylinder. Changing the relative locations of the lenses enables a continuous change in the depth of focus of the beam within the glass material. In some embodiments, a depth of the laser beam focal line within the glass material is about 0.32 mm to about 0.98 mm, preferably about 0.5 mm to about 0.98 mm, more preferably about 0.75 mm to about 0.98 mm.

In some embodiments, a distance d1 between the axicon lens and the optical element set is about 85 to about 110 mm. In some embodiments, a distance d1 between the axicon lens and the optical element set is about 95 to about 110 mm. In some embodiments, a distance d1 between the axicon lens and the optical element set is about 100 to about 110 mm. In some embodiments, a distance d1 between the axicon lens and the optical element set is about 105 to about 110 mm. In some embodiments, a distance d1 between the axicon lens and the optical element set is about 85 to about 105 mm. In some embodiments, a distance d1 between the axicon lens and the optical element set is about 85 to about 100 mm. In some embodiments, a distance d1 between the axicon lens and the optical element set is about 85 to about 95 mm. In some embodiments, a distance d1 between the axicon lens and the optical element set is about 85 to about 90 mm.

In some embodiments, a distance d3 between the optical element set and the focusing optical element is about 30 to about 90 mm. In some embodiments, a distance d3 between the optical element set and the focusing optical element is about 50 to about 90 mm. In some embodiments, a distance d3 between the optical element set and the focusing optical element is about 70 to about 90 mm. In some embodiments, a distance d3 between the optical element set and the focusing optical element is about 30 to about 70 mm. In some embodiments, a distance d3 between the optical element set and the focusing optical element is about 30 to about 50 mm.

In some embodiments, a distance d2 between the convex lens 102a and the concave lens 102b is about 1 mm to about 50 mm. In some embodiments, a distance d2 between the convex lens 102a and the concave lens 102b is about 15 mm to about 50 mm. In some embodiments, a distance d2 between the convex lens 102a and the concave lens 102b is about 30 mm to about 50 mm. In some embodiments, a distance d2 between the convex lens 102a and the concave lens 102b is about 45 mm to about 50 mm. In some embodiments, a distance d2 between the convex lens 102a and the concave lens 102b is about 1 mm to about 35 mm. In some embodiments, a distance d2 between the convex lens 102a and the concave lens 102b is about 1 mm to about 20 mm.

FIG. 5 depicts an embodiment of an optical assembly 6 having a first configuration 231, a second configuration 232, a third configuration 233, or a fourth configuration 234. The optical assembly comprises a first optical element set comprising an axicon lens 101, a collimation lens 102, and a focusing lens 103. The axicon lens 101, the collimation lens 102, and the focusing lens 103 are in a fixed position. The optical assembly further comprises a second optical element set comprising three aspherical lens. The first aspherical lens 111 and the second aspherical lens 112 are translatable relative to each other along the laser beam propagation direction. The third aspherical lens 113 is in a fixed position along the laser beam propagation direction. Changing the relative locations of the first aspherical lens 111 and the second aspherical lens 112 enables a continuous change in the depth of focus of the beam within the glass material. In some embodiments, a depth of the laser beam focal line within the glass material is about 0.43 to about 0.66 mm.

In some embodiments, a distance d1 between the first aspherical lens and the second aspherical lens is about 50 to about 71 mm. In some embodiments, a distance d2 between the second aspherical lens and the third aspherical lens is about 31 to about 48 mm.

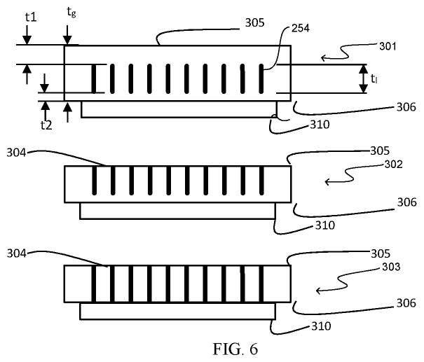

At step 308, the glass material (e.g. layer 1) and the optical assembly are translatable relative to each other, thereby laser drilling a plurality of perforations along a first plane within the material. FIG. 6 at 301 depicts multiple perforations 254 formed within layer 1, having a thickness t_{g}, via the systems and methods of the present disclosure and a semiconductor device 310 disposed on a first surface of the layer 1. The semiconductor device can be formed by a sequence of fabrication steps such as thin film deposition, oxidation or nitration, etching, polishing, and thermal and lithographic processing. Layer 1 has a first surface 305 (also referred to as a contact free surface) and a second surface 306 upon which the semiconductor device is formed. In some embodiments, the depth t₁ of the perforation 254 is less than half of the thickness t_{g} of layer 1. In some embodiments, the depth t₁ of the perforation 254 is less than a third of the thickness t_{g} of layer 1. The upper tip of the perforation 254 is positioned a distance t₁ from the contact free surface 305. The lower tip of the perforation 254 is positioned a distance t₁ from the second surface 306. In some embodiments, the perforations 254 are positioned such that t₁ is greater than t₂. At step 310, and referring to FIG. 6 at 302, the glass material of layer 1 is thinned to expose a first end 304 (i.e. the upper tip) of the plurality of perforations 254. Thinning of the glass substrate can be performed by conventional mechanical and chemical etching processes or a combination of both can be used. In the case of mechanical process, the carrier is physically grinded with abrasive materials such as diamond or SiC or similar materials until the perforations are exposed. In the case of chemical process, the carrier is immersed in HF contained liquid until the perforations are exposed. In the case of a hybrid process, the carrier can go through a mechanical grinding process first and then immerse in etchant to finish the last step.

At step 312, and referring to FIG. 6 at 303, following the thinning process, the plurality of perforations 254 are expanded through the thickness of the glass material of layer 1 to the second surface 306 by mechanical expansion, thermal expansion or chemical expansion. In the case of mechanical expansion, the perforations are expanded with mechanical stress such as bending, twisting or both. In the case of thermal expansion, a thermal gradient is induced by rapid heating of the glass material using IR sources such as laser beam, IR radiation, or hot plates. In the case of chemical expansion, an etchant is used to penetrate into the perforations and open them up.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

We claim:

1. A method comprising:
focusing a pulsed laser beam into a laser beam focal line oriented along the laser beam propagation direction via an optical assembly positioned in the beam path of the laser on the beam emergence side of the optical assembly, the optical assembly including:
an axicon lens with spherical aberration configured to generate the laser beam focal line,
an optical element set spaced part from the axicon lens, and
a focusing optical element spaced apart from the optical element set, wherein the axicon lens and the optical element set are translatable relative to each other along the laser beam propagation direction and wherein the focusing optical element is in a fixed position along the laser beam propagation direction;
directing the laser beam focal line into a glass material having a thickness of less than 5 mm, the laser beam focal line generating an induced absorption within the glass material, the induced absorption producing a perforation along the laser beam focal line within the material;
adjusting the distance between the axicon lens and the optical element to adjust the depth of the laser beam focal line within the material;
translating the glass material and the laser beam relative to each other, thereby laser drilling a plurality of perforations along a first plane within the material, wherein the depth of the perforation is less than half of the thickness of the material;

2. The method of claim 1, further comprising thinning the glass material to expose a first end of the plurality of perforations to at least one surface; and expanding the plurality of perforations through the thickness.

3. The method of claim 1, wherein a distance between the axicon lens and the optical element set is about 85 to about 110 mm.

4. The method of claim 1, wherein a distance between the optical element set and the focusing optical element is about 30 to about 90 mm.

5. The method of claim 1, wherein a depth of the laser beam focal line within the glass material is about 0.32 mm to about 0.98 mm.

6. The method of claim 1, wherein the optical element set comprises two lenses spaced a second distance apart.

7. The method of claim 6, wherein the second distance is about 1 mm to about 50 mm.

8. The method of claim 1, further comprising forming a semiconductor device on the surface of the glass material after drilling a plurality of perforations along a first plane within the material.

9. The method of claim 8, further comprising thinning the glass material after forming the semiconductor device on the surface of the glass material to expose an opening of the perforations.

10. A method comprising:
focusing a pulsed laser beam into a laser beam focal line oriented along the laser beam propagation direction via an optical assembly positioned in the beam path of the laser on the beam emergence side of the optical assembly, the optical assembly including:
a first optical element set comprising an axicon lens, a collimation lens, and a focusing lens, wherein the axicon lens, the collimation lens, and the focusing lens are in a fixed position,
a second optical element set comprising three aspherical lens, wherein the first aspherical lens and the second aspherical lens are translatable relative to each other along the laser beam propagation direction and wherein the third aspherical lens is in a fixed position along the laser beam propagation direction;
directing the laser beam focal line into a glass material having a thickness of less than 5 mm, the laser beam focal line generating an induced absorption within the glass material, the induced absorption producing a perforation along the laser beam focal line within the material;
adjusting the distance between the first aspherical lens and the second aspherical lens to adjust the depth of the laser beam focal line within the material;
translating the glass material and the laser beam relative to each other, thereby laser drilling a plurality of perforations along a first plane within the material, wherein the depth of the perforation is less than half of the thickness of the material.

11. The method of claim 10, further comprising thinning the glass material to expose a first end of the plurality of perforations to at least one surface; and expanding the plurality of perforations through the thickness.

12. The method of claim 10, wherein a distance between the first aspherical lens and the second aspherical lens is about 50 to about 71 mm.

13. The method of claim 10, wherein a distance between the second aspherical lens and the third aspherical lens is about 31 to about 48 mm.

14. The method of claim 10, wherein a depth of the laser beam focal line within the material is about 0.43 to about 0.66 mm.

15. The method of claim 10, further comprising forming a semiconductor device on the surface of the glass material after drilling a plurality of perforations along a first plane within the material.

16. The method of claim 10, further comprising thinning the glass material forming the semiconductor device on the surface of the glass material to expose an opening of the perforations.

17. An optical assembly, comprising:
an axicon lens with spherical aberration configured to generate a laser beam focal line from a laser beam;
an optical element set spaced part from the axicon lens, and
a focusing optical element spaced apart from the optical element set, wherein the axicon lens and the optical element set are translatable relative to each other along a laser beam propagation direction and wherein the focusing optical element is in a fixed position along the laser beam propagation direction.

18. The optical assembly of claim 17, wherein a distance between the axicon lens and the optical element set is about 85 to about 110 mm.

19. The optical assembly of claim 17, wherein a distance between the optical element set and the focusing optical element is about 30 to about 90 mm.

20. The optical assembly of claim 17, wherein the optical element set comprises two lenses spaced a second distance apart, wherein the second distance is about 1 mm to about 50 mm.
